(19) United States
(12) Patent Application Publication
(10) Pub. No.: US 2026/0229804 A1
(43) Pub. Date: Aug. 6, 2026

(54) CONNECTOR TERMINAL, TERMINAL ASSEMBLY, CONNECTOR AND CONNECTOR ASSEMBLY

(71) Applicant: Tyco Electronics (Shanghai) Co., Ltd., Shanghai (CN)

(72) Inventors: Jiaoyong (Mac) Liu, Shanghai (CN); Jie (Roger) Luo, Foshan (CN); Rong (Summer) Zhang, Shenzhen (CN); William (Wei) Yao, Kunshan (CN)

(73) Assignee: Tyco Electronics (Shanghai) Co., Ltd., Shanghai (CN)

(21) Appl. No.: 19/530,508

(22) Filed: Feb. 5, 2026

(30) Foreign Application Priority Data
Feb. 6, 2025 (CN) 202510132065.X

(51) Int. Cl. H01R 13/11

(52) U.S. Cl. CPC H01R 13/113

(57) ABSTRACT

A connector terminal includes a cylindrical part, two rows of elastic arms and a fixing part. The cylindrical part is adapted to be electrically connected to a power transmission component, and includes an inner cavity adapted to accommodate a liquid cooling module. The two rows of elastic arms are suitable for insertion into an insertion slot of a mating terminal. The fixing part is connected between the cylindrical part and the two rows of elastic arms. The fixing part is adapted to fix to a connector housing, and the two rows of elastic arms are vertically opposite to each other and arranged in an axial direction of the cylindrical part, for simultaneous electrical contact with the inner wall surface of the insertion slot.

### CROSS-REFERENCE TO RELATED APPLICATION

This application claims the benefit of Chinese Patent Application No. CN202510132065.X filed on Feb. 6, 2025 in the State Intellectual Property Office of China, the whole disclosure of which is incorporated herein by reference.

### FIELD OF THE INVENTION

The disclosure relates to a connector terminal, a terminal assembly comprising the connector terminal, a connector comprising the connector terminal or terminal assembly, and a connector assembly comprising the connector.

### BACKGROUND OF THE INVENTION

In the prior art, a connector terminal typically only has a single row of elastic arms, which results in limited electrical contact area between the connector terminal and the mating terminal, insufficient to meet high current transmission capabilities, such as the requirement for 1100A current transmission. In addition, in the prior art, due to the high transmission current, the temperature rise of the connector terminal can be too high, which can easily cause safety accidents.

### SUMMARY OF THE INVENTION

According to an embodiment of the present disclosure, a connector terminal includes a cylindrical part, two rows of elastic arms and a fixing part. The cylindrical part is adapted to be electrically connected to a power transmission component, and includes an inner cavity adapted to accommodate a liquid cooling module. The two rows of elastic arms are suitable for insertion into an insertion slot of a mating terminal. The fixing part is connected between the cylindrical part and the two rows of elastic arms. The fixing part is adapted to fix to a connector housing, and the two rows of elastic arms are vertically opposite to each other and arranged in an axial direction of the cylindrical part, for simultaneous electrical contact with the inner wall surface of the insertion slot.

### BRIEF DESCRIPTION OF DRAWINGS

The above and other features of the present invention will become more apparent by describing in detail exemplary embodiments thereof with reference to the accompanying drawings, in which:

FIG. 1 shows an illustrative perspective view of a terminal assembly according to an exemplary embodiment of the present invention;

FIG. 2 shows an illustrative exploded view of a terminal assembly according to an exemplary embodiment of the present invention;

FIG. 3 shows an illustrative exploded view of a connector terminal according to an exemplary embodiment of the present invention;

FIG. 4 shows an illustrative perspective view of a first terminal and an elastic support member according to an exemplary embodiment of the present invention;

FIG. 5 shows an illustrative exploded view of the first terminal and elastic support member according to an exemplary embodiment of the present invention;

FIG. 6 shows an illustrative perspective view of a connector according to an exemplary embodiment of the present invention;

FIG. 7 shows a longitudinal sectional view of a connector according to an exemplary embodiment of the present invention;

FIG. 8 shows an illustrative perspective view of a mating module according to an exemplary embodiment of the present invention;

FIG. 9 shows an illustrative exploded view of the mating module according to an exemplary embodiment of the present invention; and

FIG. 10 shows an illustrative perspective view of a connector assembly according to an exemplary embodiment of the present invention.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to an embodiment of the present disclosure, a connector terminal comprises: a cylindrical part for electrical connection to a power transmission component; two rows of elastic arms, suitable for insertion into an insertion slot of a mating terminal; and a fixing part connected between the cylindrical part and the two rows of elastic arms. The cylindrical part has an inner cavity for accommodating a liquid cooling module, the fixing part is used to fix to a connector housing, and the two rows of elastic arms are vertically opposite to each other and arranged in an axial direction of the cylindrical part, for simultaneous electrical contact with the inner wall surface of the insertion slot.

According to another embodiment, a terminal assembly comprises the above connector terminal, and a liquid cooling module which is inserted into the cylindrical part of the connector terminal for cooling the connector terminal. Similarly, according to another embodiment, a connector includes a connector housing, and the above connector terminal or the above terminal assembly, which is provided in the connector housing.

According to another embodiment of the present disclosure, a connector assembly is provided. The connector assembly comprises the above connector and a mating module. The mating module includes two mating terminals and an insulation isolation plate which is installed between the two mating terminals to electrically isolate the two mating terminals. The mating terminal has two insertion slots respectively formed on its front and rear ends, and the connector comprises two connector terminals, the two plug parts of one connector are respectively inserted into the insertion slots on the front side of the two mating terminals, and the two plug parts of the other connector are respectively inserted into the insertion slots on the rear side of the two mating terminals.

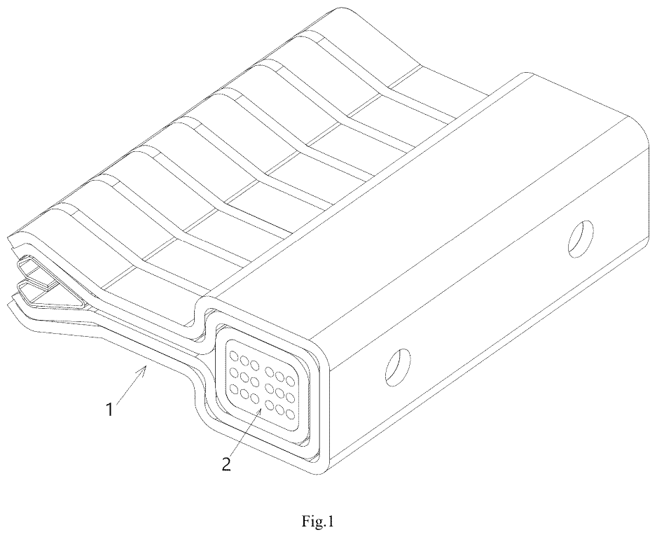

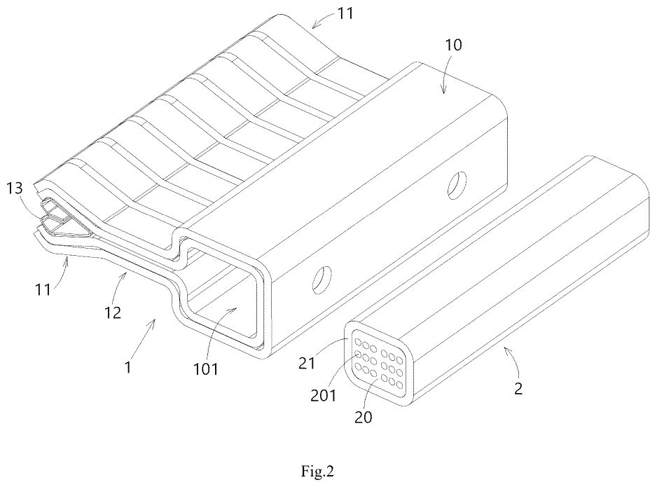

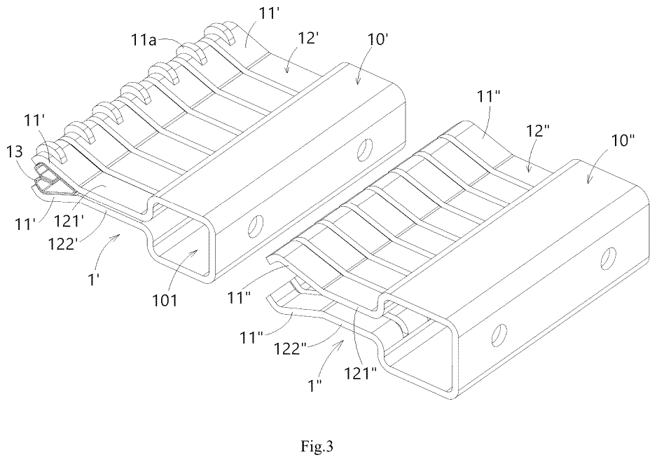

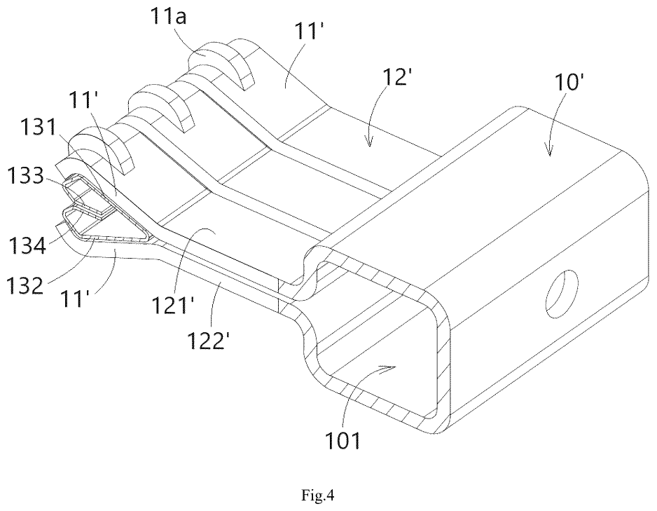

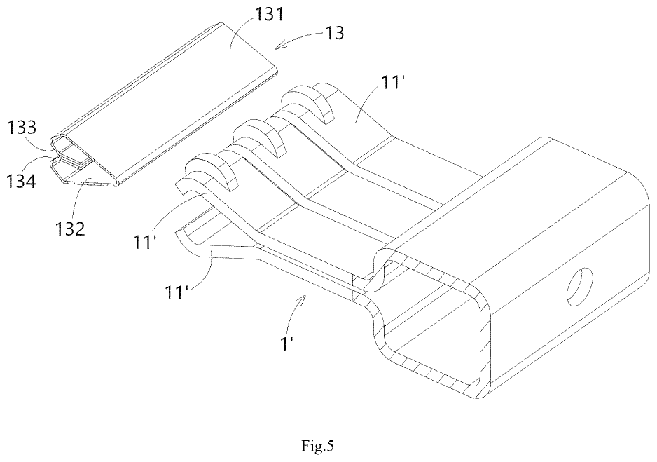

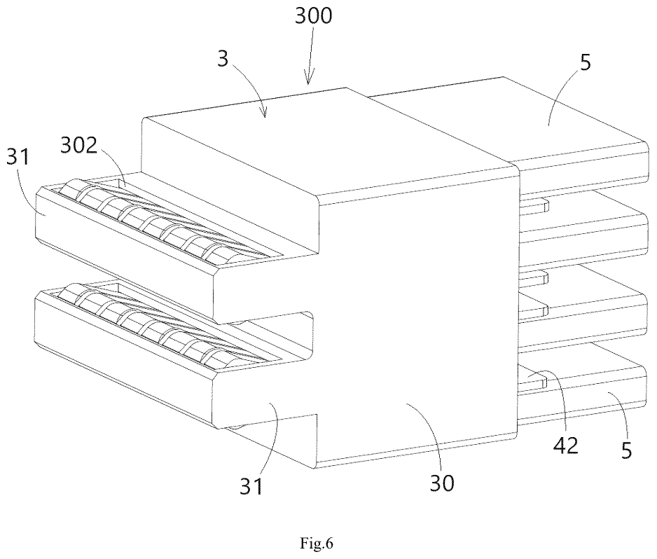

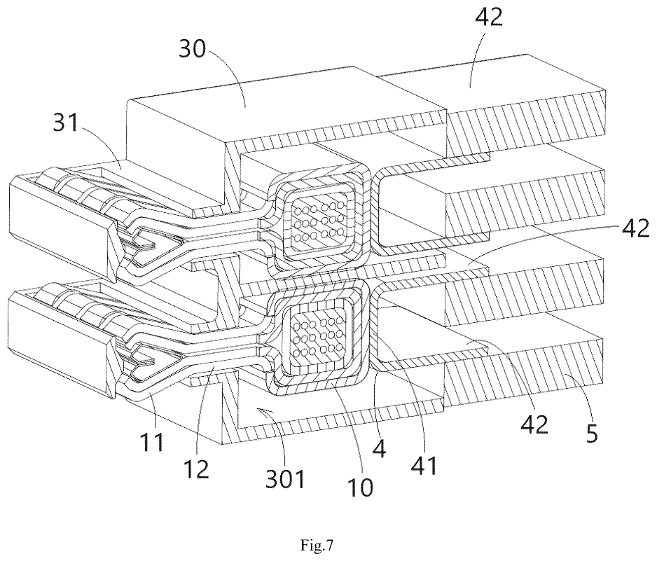

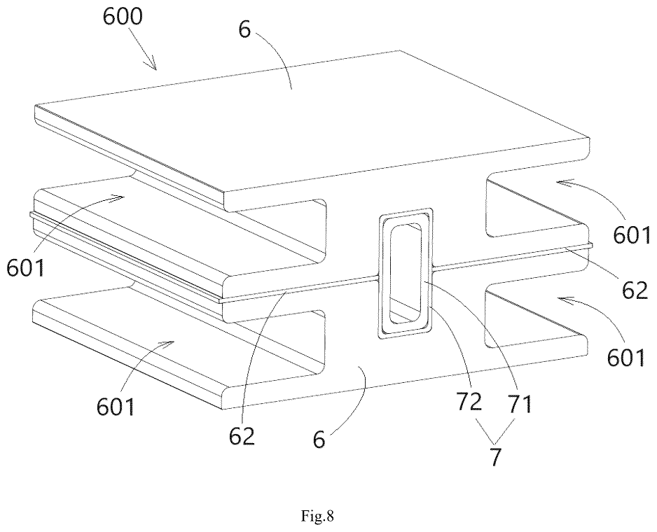

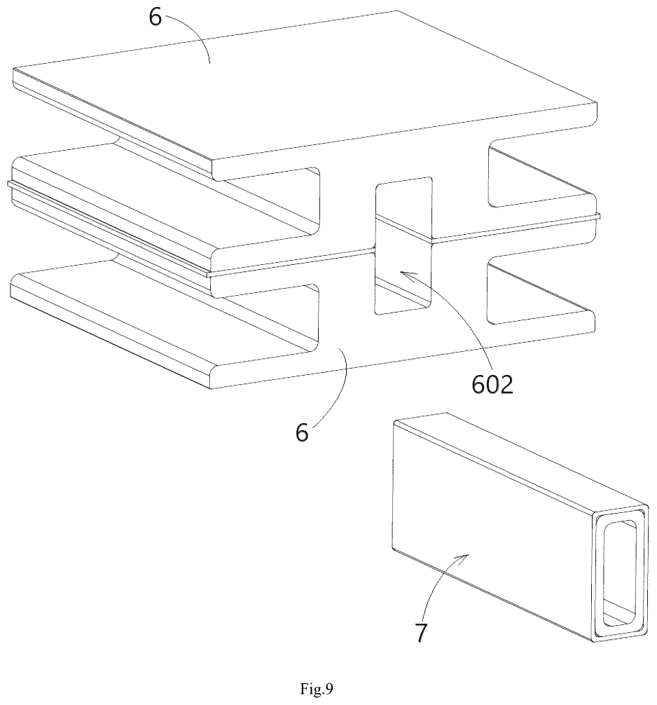

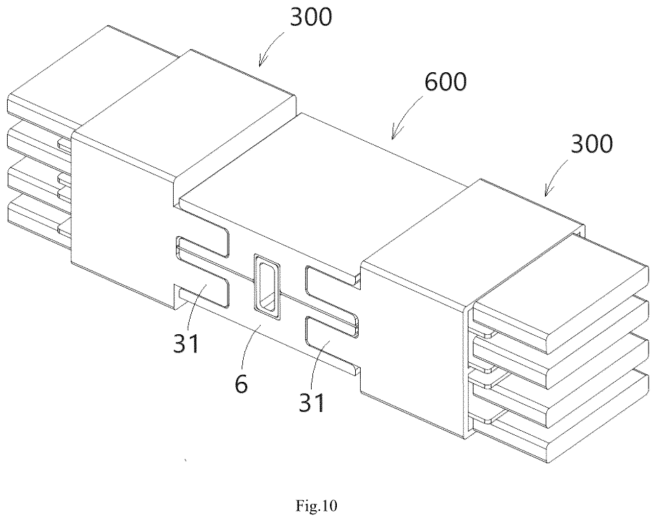

FIG. 1 shows an illustrative perspective view of a terminal assembly according to an exemplary embodiment of the present invention; FIG. 2 shows an illustrative exploded view of a terminal assembly according to an exemplary embodiment of the present invention; FIG. 3 shows an illustrative exploded view of connector terminal 1 according to an exemplary embodiment of the present invention; FIG. 4 shows an illustrative perspective view of the first terminal 1′ and the elastic support member 13 according to an exemplary embodiment of the present invention; FIG. 5 shows an illustrative exploded view of the first terminal 1′ and the elastic support member 13 according to an exemplary embodiment of the present invention; FIG. 6 shows an illustrative perspective view of a connector 300 according to an exemplary embodiment of the present invention; FIG. 7 shows a longitudinal sectional view of connector 300 according to an exemplary embodiment of the present invention; FIG. 8 shows an illustrative perspective view of a mating module 600 according to an exemplary embodiment of the present invention; FIG. 9 shows an illustrative exploded view of a mating module 600 according to an exemplary embodiment of the present invention; FIG. 10 shows an illustrative perspective view of a connector assembly according to an exemplary embodiment of the present invention.

As shown in FIGS. 1 to 10, in an exemplary embodiment of the present invention, a connector terminal 1 is disclosed. The connector terminal 1 includes a cylindrical part 10, two rows of elastic arms 11, and a fixing part 12. The cylindrical part 10 is used for electrical connection to a power transmission component 5. The two rows of elastic arms 11 are suitable for insertion into an insertion slot 601 of a mating terminal 6. The fixing part 12 is connected between the cylindrical part 10 and the two rows of elastic arms 11. The cylindrical part 10 has an inner cavity 101 for accommodating a liquid cooling module 2, the fixing part 12 is used to fix to a connector housing 3, and two rows of elastic arms 11 are vertically opposite to each other and arranged in the axial direction of the cylindrical part 10 for simultaneous electrical contact with the inner wall surface of the insertion slot 601.

As shown in FIGS. 1 to 10, in the illustrated embodiment, the connector terminal 1 includes a first terminal 1′ and a second terminal 1″ wrapped around the outer side of the first terminal 1′, making the connector terminal 1 have a double-layer structure.

As shown in FIGS. 1 to 10, in the illustrated embodiment, the first terminal 1′ includes a first cylindrical part 10′, which defines the inner cavity 101 for accommodating the liquid cooling module 2. The second terminal 1″ includes a second cylindrical part 10″, and the cylindrical part 10 of the connector terminal 1 is composed of the first cylindrical part 10′ and the second cylindrical part 10″. The first cylindrical part 10′ is accommodated in the second cylindrical part 10−, and the outer wall surface of the first cylindrical part 10′ is pressed against the inner wall surface of the second cylindrical part 10″.

As shown in FIGS. 1 to 10, in the illustrated embodiment, the first terminal 1′ further includes two rows of first elastic arms 11′, and the second terminal 1″ further includes two rows of second elastic arms 11″, with the upper row of first elastic arms 11′ resting against the inner side of the upper row of second elastic arms 11″ and the lower row of first elastic arms 11′ resting against the inner side of the lower row of second elastic arms 11″. The upper row of elastic arms 11 of connector terminal 1 is composed of the upper row of first elastic arms 11′ and the upper row of second elastic arms 11″, while the lower row of elastic arms 11 of connector terminal 1 is composed of the lower row of first elastic arms 11′ and the lower row of second elastic arms 11″.

As shown in FIGS. 1 to 10, in the illustrated embodiment, a contact protrusion 11a is formed on the end of the first elastic arm 11′, and the contact protrusion 11a is exposed from the gap between the ends of adjacent second elastic arms 11″ for electrical contact with the inner wall surface of the insertion slot 601 of the mating terminal 6.

As shown in FIGS. 1 to 10, in the illustrated embodiment, the first terminal 1′ further includes a first fixing part 12′, and the second terminal 1″ further includes a second fixing part 12″. The fixing part 12 of the connector terminal 1 is composed of the first fixing part 12′ and the second fixing part 12″. The first fixing part 12′ is connected between the first elastic arm 11′ and the first cylindrical part 10′, and the second fixing part 12″ is connected between the second elastic arm 11″ and the second cylindrical part 10″.

As shown in FIGS. 1 to 10, in the illustrated embodiment, the first fixing part 12′ includes an upper first fixing plate 121′ and a lower first fixing plate 122′. The upper first fixing plate 121′ is connected between the root of the upper row of first elastic arms 11′ and the front side of the first cylindrical part 10′. The lower first fixing plate 122′ is connected between the root of the lower row of first elastic arms 11′ and the front side of the first cylindrical part 10′. The upper first fixing plate 121′ and the lower first fixing plate 122′ are stacked together.

As shown in FIGS. 1 to 10, in the illustrated embodiment, the second fixing part 12″ includes an upper second fixing plate 121″ and a lower second fixing plate 122″. The upper second fixing plate 121″ is connected between the root of the upper row of second elastic arms 11″ and the front side of the second cylindrical part 10″. The lower second fixing plate 122″ is connected between the root of the lower row of second elastic arms 11″ and the front side of the second cylindrical part 10″. The upper second fixing plate 121″ is attached to the top surface of the upper first fixing plate 121′, and the lower second fixing plate 122″ is attached to the bottom surface of the lower first fixing plate 122′.

As shown in FIGS. 1 to 10, in the illustrated embodiment, the cross-sections of the first cylindrical part 10′, the second cylindrical part 10″, and the cylindrical part 10 are rectangular. However, the present invention is not limited to the illustrated embodiments, for example, the cross-sections of the first cylindrical part 10′, the second cylindrical part 10″, and the cylindrical part 10 may be circular or other suitable shapes.

As shown in FIGS. 1 to 10, in the illustrated embodiment, the first terminal 1′ is an integral stamped part made by stamping a single metal sheet. Similarly, the second terminal 1″ is an integral stamped part made by stamping a single metal sheet.

As shown in FIGS. 1 to 10, in the illustrated embodiment, the connector terminal further includes an elastic support member 13. The elastic support member 13 is arranged between the two rows of first elastic arms 11′ and is suitable for being compressed between the two rows of first elastic arms 11′. The elastic support member 13 is used to apply auxiliary contact force to the two rows of first elastic arms 11′ and two rows of second elastic arms 11″ to ensure reliable electrical contact between the two rows of first elastic arms 11′ and two rows of second elastic arms 11″ and the inner wall surface of the insertion slot 601 of the mating terminal 6.

As shown in FIGS. 1 to 10, in the illustrated embodiment, the elastic support member 13 includes an upper support arm 131 and a lower support arm 132. The upper support arm 131 is attached to the inner side of the upper row of first elastic arms 11′, used to support the upper row of first elastic arms 11′ and the upper row of second elastic arms 11″. The lower support arm 132 is attached to the inner side of the lower row of first elastic arms 11′, used to support the lower row of first elastic arms 11′ and lower row of the second elastic arms 11′. The rear ends of the upper support arm 131 and the lower support arm 132 are connected.

As shown in FIGS. 1 to 10, in the illustrated embodiment, the elastic support member 13 further comprises an upper end arm 133 and a lower end arm 134. The upper end arm 133 is connected to the front end of the upper support arm 131 and is bent backwards relative to the front end of the upper support arm 131. The lower end arm 134 is connected to the front end of the lower support arm 132 and is bent backwards relative to the front end of the lower support arm 132. The upper end arm 133 and the lower end arm 134 are located between the upper support arm 131 and the lower support arm 132 and are in contact with each other, for respectively supporting the upper support arm 131 and the lower support arm 132.

As shown in FIGS. 1 to 10, in the illustrated embodiment, the mechanical properties of the manufacturing material of the elastic support member 13 are superior to those of the manufacturing materials of the first terminal 1′ and the second terminal 1″. The conductivity of the manufacturing materials for the first terminal 1′ and the second terminal 1″ is superior to that of the manufacturing material for the elastic support member 13.

As shown in FIGS. 1 to 10, in the illustrated embodiment, the first terminal 1′ and the second terminal 1″ are made of copper or copper alloy, and the elastic support member 13 is made of stainless steel. Stainless steel parts have excellent mechanical properties, which can improve sufficient elastic support force and ensure reliable electrical contact between the connector terminal 1 and the mating terminal 6.

As shown in FIGS. 1 to 10, in another exemplary embodiment of the present invention, a terminal assembly is also disclosed. The terminal assembly includes the aforementioned connector terminal 1 and a liquid cooling module 2. The liquid cooling module 2 is inserted into the cylindrical part 10 of the connector terminal 1 for cooling the connector terminal 1.

As shown in FIGS. 1 to 10, in the illustrated embodiment, the liquid cooling module 2 includes a thermal block 20 and a thermal pad 21. A liquid cooling channel 201 is formed in the thermal block 20 for circulating cooling liquid. The thermal pad 21 is wrapped around the outside of the thermal block 20 and pressed between the inner wall surface of the first cylindrical part 10′ and the outer peripheral surface of the thermal block 20. The thermal pad 21 is used to transfer heat from the connector terminal 1 to the thermal block 20 and electrically isolate the thermal block 20 from the connector terminal 1.

As shown in FIGS. 1 to 10, in the illustrated embodiment, multiple liquid cooling channels 201 are formed in the thermal block 20, which extend along the axial direction of the cylindrical part 10 and are distributed in an array.

As shown in FIGS. 1 to 10, in the illustrated embodiment, the thermal pad 21 is a thermal layer 72 injected onto the thermal block 20 or a thermal sleeve fitted onto the thermal block 20.

As shown in FIGS. 1 to 10, in another exemplary embodiment of the present invention, a connector is also disclosed. The connector comprises a connector housing 3 and the aforementioned connector terminal 1 or terminal assembly. The aforementioned connector terminal 1 or the aforementioned terminal assembly is arranged in the connector housing 3.

As shown in FIGS. 1 to 10, in the illustrated embodiment, the connector housing 3 includes a main housing part 30 and a plug part 31. The plug part 31 is connected to the front wall of the main housing part 30 and is suitable for insertion into the insertion slot 601 of the mating terminal 6. The cylindrical part 10 of connector terminal 1 is accommodated in the main housing part 30, the two rows of elastic arms 11 of connector terminal 1 are accommodated in the plug part 31, and the fixing part 12 of connector terminal 1 is fixed in the plug part 31. Windows 302 are formed on the top and bottom surfaces of the plug part 31, respectively. The two rows of elastic arms 11 of the connector terminal 1 are exposed through the windows 302 on the plug part 31, for simultaneous electrical contact with the inner wall surface of the insertion slot 601 of the mating terminal 6.

As shown in FIGS. 1 to 10, in the illustrated embodiment, two adjacent upper and lower receiving chambers 301 are formed in the main housing part 30. The connector housing 3 includes two plug parts 31, and the connector includes two connector terminals 1. The cylindrical parts 10 of the two connector terminals 1 are respectively accommodated in two receiving chambers 301, the elastic arms 11 of the two connector terminals 1 are respectively accommodated in two plug parts 31, and the fixing parts 12 of the two connector terminals 1 are respectively fixed in two plug parts 31.

As shown in FIGS. 1 to 10, in the illustrated embodiment, the connector also includes two electrical adapters 4. Two electrical adapters 4 are respectively installed in the two receiving chambers 301 of the connector housing 3 and electrically connected to the rear sides of the cylindrical parts 10 of the two connector terminals 1. The electrical adapter 4 has a welding plate 42 extending from the rear side of the connector housing 3, which is used for welding to the power transmission component 5.

As shown in FIGS. 1 to 10, in the illustrated embodiment, the cross-section of the electrical adapter 4 is U-shaped, and the electrical adapter 4 includes a bottom plate 41 and two welding plates 42 connected to the upper and lower sides of the bottom plate 41, respectively. The bottom plate 41 of the electrical adapter 4 is fixed to the rear side of the cylindrical part 10 of the connector terminal 1, and two welding plates 42 extend from the rear side of the connector housing 3 for respectively welding to two power transmission components 5.

As shown in FIGS. 1 to 10, in the illustrated embodiment, the connector further comprises four power transmission components 5, which are respectively welded to four welding plates 42 of two electrical adapters 4. In the illustrated embodiment, the power transmission component 5 is a busbar. However, the present invention is not limited to the illustrated embodiments, for example, the power transmission component 5 may also be a cable.

As shown in FIGS. 1 to 10, in another exemplary embodiment of the present invention, a connector assembly is also disclosed. The connector assembly includes the aforementioned connector 300 and a mating module 600. The mating module 600 includes two mating terminals 6 and an insulation isolation plate 62. The insulation isolation plate 62 is set between two mating terminals 6, used to electrically isolate the two mating terminals 6 from each other. The mating terminal 6 has two insertion slots 601 formed in its front and rear ends, respectively. The connector includes two connector terminals 1. Two plug parts 31 of one connector 300 are respectively inserted into the insertion slots 601 on the front side of two mating terminals 6; The two plug parts 31 of the other connector 300 are respectively inserted into the insertion slots 601 on the rear side of the two mating terminals 6.

As shown in FIGS. 1 to 10, in the illustrated embodiment, laterally extending notches are formed in two mating terminals 6, and the notches of the two mating terminals 6 are combined into a transverse slot 602. The mating module 600 also includes a cooling module 7 inserted into the transverse slot 602 for cooling the two mating terminals 6.

As shown in FIGS. 1 to 10, in the illustrated embodiment, the cooling module 7 includes a liquid cooling tube 71 and a thermal conductive layer 72. The liquid cooling tube 71 is used for circulating cooling liquid. The thermal conductive layer 72 is formed outside the liquid cooling tube 71. The thermal conductive layer 72 is in thermal contact with the inner wall surface of the transverse slot 602, used to transfer the heat of the mating terminal 6 to the liquid cooling tube 71 and electrically isolate the mating terminal 6 from the liquid cooling tube 71.

Compared with existing technologies, the present invention has at least the following advantages: in the same space, the present invention can increase the electrical contact area and current carrying capacity of the connector terminal by at least twice, greatly reducing the contact impedance and body resistance of the connector terminal; The present invention can fully cool the connector terminals using a liquid cooling module, which not only prevents excessive temperature rise of the connector terminals, but also further improves the current carrying capacity of the connector terminals.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A connector terminal, comprising:
a cylindrical part for electrical connection to a power transmission component, and including an inner cavity adapted to accommodate a liquid cooling module;
two rows of elastic arms, suitable for insertion into an insertion slot of a mating terminal; and
a fixing part connected between the cylindrical part and the two rows of elastic arms, the fixing part adapted to fix to a connector housing, and the two rows of elastic arms are vertically opposite to each other and arranged in an axial direction of the cylindrical part, for simultaneous electrical contact with the inner wall surface of the insertion slot.

2. The connector terminal according to claim 1, wherein the connector terminal comprises a double-layer structure including a first terminal and a second terminal wrapped around the outer side of the first terminal.

3. The connector terminal according to claim 2, wherein:
the first terminal includes a first cylindrical part, which defines the inner cavity for accommodating the liquid cooling module;
the second terminal includes a second cylindrical part, and the cylindrical part of the connector terminal is composed of the first cylindrical part and the second cylindrical part; and
the first cylindrical part is accommodated in the second cylindrical part and the outer wall surface of the first cylindrical part is pressed against the inner wall surface of the second cylindrical part.

4. The connector terminal according to claim 3, wherein:
the first terminal further includes upper and lower rows of first elastic arms, and the second terminal further comprises upper and lower rows of second elastic arms, wherein the upper row of first elastic arms is attached to the inner side of the upper row of second elastic arms, and the lower row of first elastic arms is attached to the inner side of the lower row of second elastic arms; and
the upper row of elastic arms of the connector terminal includes the upper row of first elastic arms and the upper row of second elastic arms, and the lower row of elastic arms of the connector terminal is composed of the lower row of first elastic arms and the lower row of second elastic arms.

5. The connector terminal according to claim 4, wherein a contact protrusion is formed on the end of the first elastic arm, and the contact protrusion is exposed from the gap between the ends of adjacent second elastic arms for electrical contact with the inner wall surface of the insertion slot of the mating terminal.

6. The connector terminal according to claim 4, wherein the first terminal further includes a first fixing part, and the second terminal further comprises a second fixing part, the fixing part of the connector terminal is composed of the first fixing part and the second fixing part, and the first fixing part is connected between the first elastic arm and the first cylindrical part, and the second fixing part is connected between the second elastic arm and the second cylindrical part.

7. The connector terminal according to claim 6, wherein the first fixing part comprises:
an upper first fixing plate which is connected between the root of the upper row of first elastic arms and the front side of the first cylindrical part; and
a lower first fixing plate which is connected between the root of the lower row of first elastic arms and the front side of the first cylindrical part, the upper first fixing plate and the lower first fixing plate are stacked together.

8. The connector terminal according to claim 7, wherein the second fixing part comprises:
an upper second fixing plate which is connected between the root of the upper row of second elastic arms and the front side of the second cylindrical part; and
a lower second fixing plate which is connected between the root of the lower row of second elastic arms and the front side of the second cylindrical part, the upper second fixing plate is attached to the top surface of the upper first fixing plate, and the lower second fixing plate is attached to the bottom surface of the lower first fixing plate.

9. The connector terminal according to claim 3, wherein the cross-sections of the first cylindrical part, the second cylindrical part, and the cylindrical part are rectangular or circular.

10. The connector terminal according to claim 2, wherein at least one of the first terminal or the second terminal is an integral stamped part.

11. The connector terminal according to claim 4, further comprising an elastic support member arranged between the two rows of first elastic arms and adapted to be compressed between the two rows of first elastic arms, the elastic support member is used to apply auxiliary contact force to the two rows of first elastic arms and the two rows of second elastic arms to ensure reliable electrical contact between the two rows of first elastic arms and the two rows of second elastic arms and the inner wall surface of the insertion slot of the mating terminal.

12. The connector terminal according to claim 11, wherein the elastic support member comprises:
an upper support arm which is attached to the inner side of the upper row of first elastic arms, used to support the upper row of first elastic arms and the upper row of second elastic arms; and
a lower support arm which is attached to the inner side of the lower row of first elastic arms, used to support the lower row of first elastic arms and the lower row of second elastic arms, the rear ends of the upper support arm and the lower support arm are connected.

13. The connector terminal according to claim 12, wherein the elastic support member further comprises:
an upper end arm which is connected to the front end of the upper support arm and bent backwards relative to the front end of the upper support arm; and
a lower end arm which is connected to the front end of the lower support arm and bent backwards relative to the front end of the lower support arm, the upper end arm and the lower end arm are located between the upper support arm and the lower support arm and are in contact with each other, for respectively supporting the upper support arm and the lower support arm.

14. The connector terminal according to claim 13, wherein:
the mechanical properties of the manufacturing material of the elastic support member are superior to those of the manufacturing material of the first terminal and the second terminal; and
the conductivity of the manufacturing material of the first terminal and the second terminal is superior to that of the manufacturing material of the elastic support member.

15. The connector terminal according to claim 14, wherein the first terminal and the second terminal are made of copper or copper alloy, and the elastic support member is made of stainless steel.

16. A terminal assembly, comprising:
a connector terminal, including:
a cylindrical part for electrical connection to a power transmission component, and including an inner cavity;
two rows of elastic arms, suitable for insertion into an insertion slot of a mating terminal; and
a fixing part connected between the cylindrical part and the two rows of elastic arms, the fixing part adapted to fix to a connector housing, and the two rows of elastic arms are vertically opposite to each other and arranged in an axial direction of the cylindrical part, for simultaneous electrical contact with the inner wall surface of the insertion slot; and
a liquid cooling module inserted into the inner cavity of the cylindrical part of the connector terminal for cooling the connector terminal.

17. The terminal assembly according to claim 16, wherein the liquid cooling module comprises:
a thermal block which is formed with a liquid cooling channel for flowing cooling liquid; and
a thermal pad wrapped around the outside of the thermal block and pressed between the inner wall surface of the first cylindrical part and the outer peripheral surface of the thermal block, the thermal pad is adapted to transfer the heat of the connector terminal to the thermal block and electrically isolate the thermal block from the connector terminal.

18. The terminal assembly according to claim 17, wherein multiple liquid cooling channels are formed in the thermal block, which extend along the axial direction of the cylindrical part and are distributed in an array.

19. The terminal assembly according to claim 17, wherein the thermal pad is a thermal layer injected onto the thermal block or a thermal sleeve fitted onto the thermal block.

20. A connector, comprising:
a connector housing; and
a terminal assembly provided in the connector housing, including:
a connector terminal, having:
a cylindrical part for electrical connection to a power transmission component, and including an inner cavity;
two rows of elastic arms, suitable for insertion into an insertion slot of a mating terminal; and
a fixing part connected between the cylindrical part and the two rows of elastic arms, the fixing part adapted to fix to a connector housing, and the two rows of elastic arms are vertically opposite to each other and arranged in an axial direction of the cylindrical part, for simultaneous electrical contact with the inner wall surface of the insertion slot; and
a liquid cooling module inserted into the inner cavity of the cylindrical part of the connector terminal for cooling the connector terminal.

21. The connector according to claim 20, wherein the connector housing comprises:
a main housing part; and
a plug part which is connected to the front wall of the main housing part and is suitable for insertion into the insertion slot of the mating terminal, the cylindrical part of the connector terminal is accommodated in the main housing part, the two rows of elastic arms of the connector terminal are accommodated in the plug part, and the fixing part of the connector terminal is fixed in the plug part, wherein windows are respectively formed on the top and bottom surfaces of the plug part, and the two rows of elastic arms of the connector terminal are exposed through the windows on the plug part for simultaneous electrical contact with the inner wall surface of the insertion slot of the mating terminal.

22. The connector according to claim 21, wherein:
two adjacent upper and lower receiving chambers are formed in the main housing part, the connector housing comprises two plug parts, and the connector comprises two connector terminals; and
the cylindrical parts of the two connector terminals are respectively accommodated in the two receiving chambers, the elastic arms of the two connector terminals are respectively accommodated in the two plug parts, and the fixing parts of the two connector terminals are respectively fixed in the two plug parts.

23. The connector according to claim 22, further comprising two electrical adapters respectively installed in the two receiving chambers of the connector housing and electrically connected to the rear sides of the cylindrical parts of the two connector terminals, the electrical adapter has a welding plate extending from the rear side of the connector housing, which is used for welding to a power transmission component.

24. The connector according to claim 23, wherein:
he cross-section of the electrical adapter is U-shaped, and the electrical adapter comprises a bottom plate and two welding plates connected to the upper and lower sides of the bottom plate, respectively; and
the bottom plate of the electrical adapter is fixed to the rear side of the cylindrical part of the connector terminal, and the two welding plates extend from the rear side of the connector housing for respectively welding to two power transmission components.

25. The connector according to claim 24, further comprising four power transmission components which are respectively welded to the four welding plates of the two electrical adapters.

26. The connector according to claim 20, further comprising a mating module, including:
two mating terminals; and
an insulation isolation plate which is installed between the two mating terminals to electrically isolate the two mating terminals, the mating terminal has two insertion slots respectively formed on its front and rear ends, and the connector comprises two connector terminals, the two plug parts of one connector are respectively inserted into the insertion slots on the front side of the two mating terminals, and the two plug parts of the other connector are respectively inserted into the insertion slots on the rear side of the two mating terminals.

27. The connector according to claim 26, wherein:
the two mating terminals are respectively formed with laterally extending notches, and the notches of the two mating terminals are combined into a transverse slot; and
the mating module further comprises a cooling module inserted into the transverse slot for cooling the two mating terminals.

28. The connector according to claim 27, wherein the cooling module comprises:
a liquid cooling tube, used for flowing cooling liquid; and
a thermal conductive layer which is formed outside the liquid cooling tube, the thermal conductive layer is in thermal contact with the inner wall surface of the transverse slot, used to transfer the heat of the mating terminal to the liquid cooling tube and electrically isolate the mating terminal from the liquid cooling tube.
